(19) United States
(12) Patent Application Publication
(10) Pub. No.: US 2007/0159087 A1
(43) Pub. Date: Jul. 12, 2007

(54) ORGANIC LIGHT-EMITTING DEVICE

(75) Inventors: Chung-Chun Lee, Yunlin County (TW); Shi-Hao Li, Taipei County (TW); Chin-Hsin Chen, Taipei City (TW); Shih-Feng Hsu, Taoyuan County (TW); Hsiao-Wen Huang, Tainan County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORP., Hsinchu 300 (TW)

(21) Appl. No.: 11/423,998

(22) Filed: Jun. 14, 2006

(30) Foreign Application Priority Data
Jan. 9, 2006 (TW) 95100750

(51) Int. Cl. H05B 33/00

(52) U.S. Cl. 313/506; 313/504

(57) ABSTRACT

An organic light-emitting device (OLED). The device comprises a metal anode, a composite cathode and a multi-layer organic material interposed therebetween. The multi-layer organic material comprises a fluorocarbon layer contacting the metal anode. The composite cathode comprises a low work function metal layer, a low activity metal layer overlying the low work function metal layer and a cap layer overlying the low activity metal layer.

### BACKGROUND OF THE INVENTION

1. Field of the Invention

The invention relates to a flat panel display (FPD), and in particular to an organic light-emitting diodes (OLEDS) capable of improved image color quality.

2. Description of the Related Art

Organic light-emitting diodes (OLEDs) are active lighting devices using organic materials. Compared with conventional inorganic LEDs, OLEDs can be easily fabricated on a large substrate by forming an amorphous silicon layer thereon. Additionally, displays utilizing OLEDs require no backlight module, such that the manufacturing process is simpler and costs are reduced. OLED technology is highly developed and can be employed in small panels such as those in personal digital assistants (PDAs) or digital cameras.

FIG. 1 illustrates a conventional organic light-emitting device. The organic light-emitting device 10 comprises an anode 100, a cathode 114 and a multi-layer organic material 110 interposed therebetween. The multi-layer organic material 110 comprises a hole transport layer (HTL) 104 adjacent to the anode 100, a electron transport layer (ETL) 108 adjacent to the cathode 114 and an electroluminescent layer 106 interposed therebetween.

When an electrical potential difference is applied between the anode 100 and the cathode 114, electrons are injected into the electron transport layer 108 from the cathode 114 and then pass through the electron transport layer 108 and the electro-luminescent layer 106. At the same time, holes are injected into the hole transport layer 104 from the anode 100 and then pass therethrough. The injected electrons and holes are recombined at the interface of the electro-luminescent layer 106 and the hole transport layer 104, releasing energy as light.

Typically, organic light-emitting devices are classified into bottom-emitting and top-emitting types. Full color active matrix organic light-emitting displays (AM-OLEDs) are constructed of white OLED and color filters. For fall color AM-OLEDs, however, providing a constant and uniform driving current is very important. In order to obtain a constant and uniform driving current, it is required to incorporate four or more thin film transistors (TFTs) in combination with one capacitor. The light-emitting area of the bottom-emitting OLED is limited by the number of TFTs. When the number of TFTs fabricated on the substrate is increased, the aperture ratio (AR) of each pixel of the bottom-emitting OLED may be reduced. In order to maintain the brightness of the panel, power consumption may be increased due to providing higher driving current density, thus reducing the lifetime of OLEDs. Conversely, the light-emitting area of top-emitting OLEDs is not limited by the number of TFTs, thus the lifetime of OLEDs is not reduced. For white top-emitting OLEDs, however, interference may occur due to microcavity phenomena in top-emitting OLEDs, such that white light is transformed into a mono-chromatic light. That is, microcavity phenomena may reduce the full width at half maxima (FWHM). As a result, it is difficult to provide white light emission because a broad emissive band cannot be obtained, thus OLED efficiency is reduced.

### BRIEF SUMMARY OF THE INVENTION

A detailed description is given in the following embodiments with reference to the accompanying drawings. An organic light-emitting device is provided. An embodiment of an organic light-emitting device. The device comprises a metal anode, a composite cathode and a multi-layer organic material interposed therebetween. The multi-layer organic material comprises a fluorocarbon layer contacting the metal anode. The composite cathode comprises a low work function metal layer, a low activity metal layer overlying the low work functions metal layer and a cap layer overlying the low activity metal layer.

### BRIEF DESCRIPTION OF THE DRAWINGS

The invention can be more fully understood by reading the subsequent detailed description and examples with references made to the accompanying drawings, wherein:

FIG. 1 is a cross-section of a conventional organic light-emitting device;

FIG. 2 is a cross-section of an embodiment of organic light-emitting device;

FIG. 3 is a diagram showing the relationship between the reflectance (%) of an anode and the wavelength (nm) of light; and

FIG. 4 is a diagram showing the relationship between the electro-luminescent intensity (a.u) and the wavelength (nm) of light.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention relates to an improved organic light-emitting device (OLED). FIG. 2 illustrates an embodiment of an OLED 20, comprising a metal anode 200, a composite cathode 218 and a multi-layer organic material 210 interposed therebetween. The metal anode 200 may comprise silver or aluminum.

In this embodiment, the multi-layer organic material 210 comprises a hole injection layer (HIL) 201 adjacent to the metal anode 200, a hole transport layer (HTL) (not shown) disposed on the hole injection layer 201, an electro-luminescent layer (EL) (not shown) disposed on the hole transport layer, an electron transport layer (ETL) (not shown) disposed on the electro-luminescent layer and an electron injection layer (EIL) (not shown) between the electron transport layer and the composite cathode 218. The multi-layer organic material 210 has a thickness of about 1000 Å to 5000 Å.

Moreover, the hole injection layer 201 disposed on the metal anode 200 and contacting thereof may comprise fluorocarbon (CFₓ). For example, the hole injection layer 201 may comprise hydrogen-containing fluorocarbon (CHF₃). The fluorocarbon layer 201 serving as a hole injection layer may reduce the energy barrier between the multi-layer organic material 210 and the metal anode 200. Moreover, the fluorocarbon layer (hole injection layer) 201 may also reduce the reflectance of the metal anode 200, thereby mitigating light interference effect.

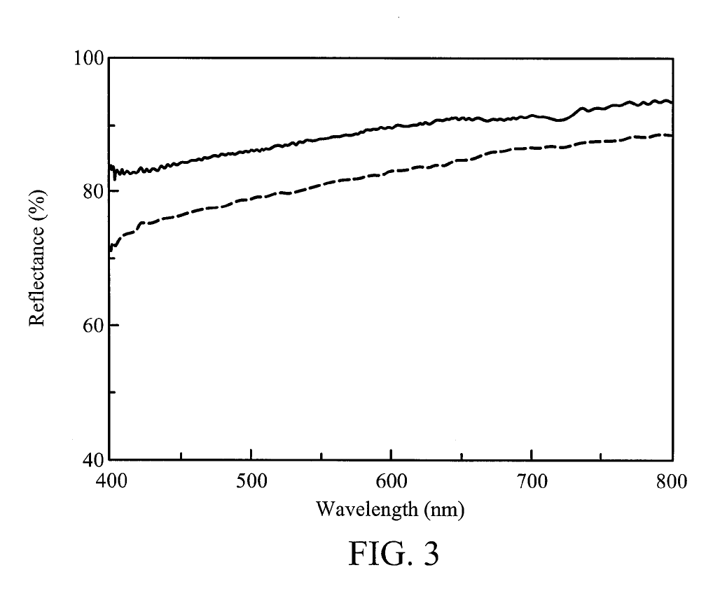

FIG. 3 illustrates a diagram showing the relationship between the reflectance (%) of an anode and the wavelength (um), in which the solid curve line represents a single silver layer having a thickness of about 200 nm and the dotted curve line represents a dual layer consisting of a silver layer having a thickness of about 200 nm and an overlying fluorocarbon layer. As shown in FIG. 3, the fluorocarbon layer (hole injection layer) 201 may reduce the reflectance of the metal anode (e.g. silver layer) 200 under various wavelengths of light. Additionally, in this embodiment, the electro-luminescent layer in the multi-layer organic material 210 may comprise white light emissive material. Moreover, the white light emissive material may comprise more than two kinds of dopant.

In this embodiment, the composite cathode 218 comprises a low work function metal layer 212 and a low activity metal layer 214 disposed thereon. Compared to the cathode using a single thin metal layer, the composite cathode 218 may itself increase conductivity. In this embodiment, the low work function metal layer 212 may comprise alkali or alkaline-earth metal. For example, the low work function metal layer 212 may comprise calcium. Moreover, the low work function metal layer 212 has a thickness of about 50 Å to 200 Å. Here, the term of “low work finction” indicates a work function not greater than 3.0 eV.

Moreover, the low activity metal layer 214 may comprise silver, aluminum or copper. The low activity metal layer 214 has a thickness of about 50 Å to 200 Å. Here, the term of “low activity” indicates a work functions greater than the electron affinity of oxygen (i.e. about 3.5 eV).

In this embodiment, in order to further improve the light emitting color of the organic light-emitting device 20, a cap layer 216 with suitable refractive index and transmittance is required for composite cathode 218, which may be disposed on the low activity metal layer 214. For example, the cap layer 216 has a refractive index of more than 2.0. Moreover, the cap layer 216 has a transmittance more than 8.0. Accordingly, the cap layer 216 may comprise SnO₂, WO₃, ZnS or ZnSe. Additionally, the thickness of the cap layer 216 must be controlled to within a specific range, thereby preventing the transmittance of the composite cathode 218 from being seriously reduced. In this embodiment, the cap layer 216 has a thickness of about 50 Å to 500 Å, and 75 to 300 Å is preferable.

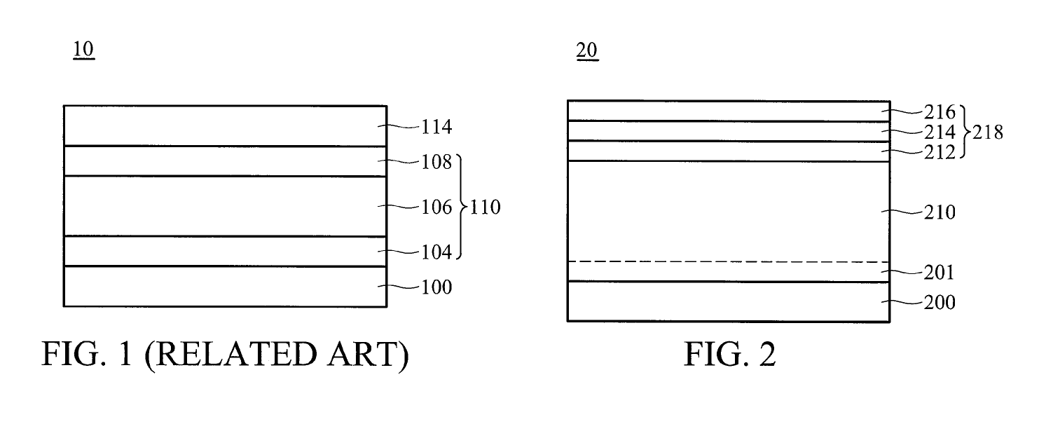

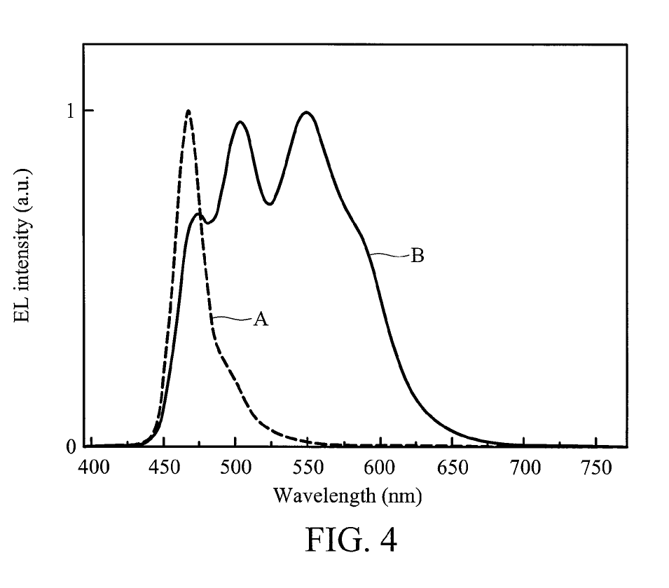

FIG. 4 illustrates a diagram showing the relationship between the electro-luminescent intensity (a.u) and the wavelength (nm) of light, in which the curve A represents a conventional white organic light-emitting device 10, as shown in FIG. 1, and the curve B represents an embodiment of white organic light-emitting device 20, as shown in FIG. 2. As shown in FIG. 4, in the conventional white organic light-emitting device 10 without a cap layer and a fluorocarbon layer, white light emitted from the electro-luminescent layer is transformed into a mono-chromatic light because the microcavity phenomena induces reduction of the full width at half maxima (FWHM). Conversely, in the white organic light-emitting device 20 having the cap layer 216 and the fluorocarbon layer 201, white light emitted from the electro-luminescent layer still have a broad emissive band.

Accordingly, the organic light-emitting device of the invention can be applied to full color AMOLEDs, and in particular to top-emitting OLEDs. Moreover, the organic light-emitting device of the invention can provide a constant and uniform driving current while improving the light emitting color of a display, thereby increasing display efficiency.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light-emitting device, comprising:
a metal anode;
a multi-layer organic material disposed on the metal anode, comprising a fluorocarbon layer contacting the metal anode; and
a composite cathode disposed on the multi-layer organic material, comprising:
a low work function metal layer;
a low activity metal layer disposed on the low work function metal layer; and
a cap layer disposed on the low activity metal layer.

2. The device as claimed in claim 1, wherein the metal anode comprises silver or aluminum.

3. The device as claimed in claim 1, wherein the multi-layer organic material comprises white light emissive material.

4. The device as claimed in claim 1, wherein the multi-layer organic material comprises a light emissive material with more than two kinds of dopants.

5. The device as claimed in claim 1, wherein the multi-layer organic material has a thickness of about 1000 Å to 5000 Å.

6. The device as claimed in claim 1, wherein the low work functions metal layer comprises alkali or alkaline-earth metal.

7. The device as claimed in claim 1, wherein the low work function metal layer comprises calcium.

8. The device as claimed in claim 1, wherein the low work function metal layer has a thickness of about 50 Å to 200 Å.

9. The device as claimed in claim 1, wherein the low activity metal layer comprises silver, aluminum or copper.

10. The device as claimed in claim 1, wherein the low activity metal layer has a thickness of about 50 Å to 200 Å.

11. The device as claimed in claim 1, wherein the cap layer comprises SnO₂, WO₃, ZnS or ZnSe.

12. The device as claimed in claim 1, wherein the cap layer has a thickness of about 50 to 500 Å.

13. The device as claimed in claim 1, wherein the cap layer has a thickness of about 75 to 300 Å.

14. The device as claimed in claim 1, wherein the cap layer has a refractive index more than 2.0.

15. The device as claimed in claim 1, wherein the cap layer has a transmittance more than 8.0.
